(19) United States
(12) Patent Application Publication
(10) Pub. No.: US 2022/0324696 A1
(43) Pub. Date: Oct. 13, 2022

(54) MEMS SWITCH INCLUDING A CAP CONTACT

(71) Applicant: Robert Bosch GmbH, Stuttgart (DE)

(72) Inventors: Bernd Klein, Reutlingen (DE); Jochen Reinmuth, Reutlingen (DE); Lutz Mueller, Aichtal (DE); Matthew Lewis, Reutlingen (DE)

(21) Appl. No.: 17/715,233

(22) Filed: Apr. 7, 2022

(30) Foreign Application Priority Data
Apr. 12, 2021 (DE) 10 2021 203 574.4

(51) Int. Cl. B81B 3/00

(52) U.S. Cl. CPC B81B 3/0018; B81B 2201/016; B81B 2203/033; B81B 2203/0307

(57) ABSTRACT

A micromechanical switch including a first substrate with a micromechanical functional layer in which a deflectable switching element is formed, and with a second substrate that is connected to the first substrate. The second substrate is situated at a distance above the switching element. The switching element includes an electrically conductive first contact area and is deflectable toward the second substrate. The second substrate, at an internal side, includes an electrically conductive second contact area that is situated in such a way that the switching element together with the first contact area may be applied to the second contact area in order to close an electrical contact. A method for manufacturing a micromechanical switch is also described.

### FIELD

The present invention is directed to a micromechanical switch that includes a first substrate with a micromechanical functional layer in which a deflectable switching element is formed, and with a second substrate that is connected to the first substrate, the second substrate being situated at a distance above the switching element, the switching element including an electrically conductive first contact area and being deflectable toward the second substrate.

### BACKGROUND INFORMATION

Conventional relays are driven via a solenoid, have a certain non-negligible current consumption in the switched-on state, and are relatively large.

In addition to the conventional magnetically operated relays, capacitively actuatable MEMS switches have also recently come into use. They have very low current consumption due to their drive principle. For example, the ADGM1304 MEMS switch from Analog Devices is available, which is manufactured in surface micromechanics (FIG. 1). The switching element has a design that is movable out of the substrate plane (out-of-plane).

German Patent Application No. DE 10 2021 202 238.3 describes a capacitively actuatable MEMS switch including a switching element that is movable in parallel to the substrate plane (in-plane) (FIG. 2), and an associated manufacturing method (FIG. 2).

The movable parts of the MEMS relay are usually closed with a cap wafer in order to protect the sensitive mechanical structures and to obtain a defined atmosphere for the electrical contacts.

MEMS relays have many advantages over conventional relays, such as quick switching times, low current consumption, small installation space, and many more. However, the conventional manufacturing methods for MEMS relays are complicated, expensive, and are subject to several undesirable restrictions.

To produce a movable contact and a capacitive drive, in most cases the operation is carried out using a sacrificial layer process. In the first example, in the manufacturing method a sacrificial layer is necessary between the lever structure and the contact surface. In the second case, multiple etchings are necessary in order to separate the metal, the insulating layer, and the silicon layer in the contact area. In addition, it is necessary to etch the sacrificial layer underneath the silicon layer in order to expose the structures and thus make them movable.

The selection of the metals and of the etching processes for manufacturing the relays is subject to very stringent limitations, since the metals as well as the etching processes used must in each case be compatible with one another. On the one hand this results in a costly manufacturing process, and on the other hand, in the use of nonoptimal metal systems.

### SUMMARY

An object of the present invention is to provide a MEMS switch and an associated manufacturing method for which the material for the switching contacts may be selected independently of the manufacturing process, in particular independently of the movable micromechanical switching portion.

The present invention is directed to a micromechanical switch that includes a substrate with a micromechanical functional layer in which a deflectable switching element is formed, and with a second substrate that is connected to the first substrate, the second substrate being situated at a distance above the switching element, and the switching element including an electrically conductive first contact area and being deflectable toward the second substrate.

In accordance with the present invention, the second substrate at an internal side includes an electrically conductive second contact area that is situated in such a way that the switching element together with the first contact area may be applied to the second contact area in order to close an electrical contact.

Moreover, the present invention relates to a method for manufacturing a micromechanical switch.

In accordance with an example embodiment of the present invention, it is provided to produce a movable contact between two wafers that are bonded to one another. A switching element in the form of a movable MEMS structure that may carry out an out-of-plane movement and that includes a first electrical contact area is formed on a first substrate. A fixed second electrical contact area is formed on a second substrate. The first and the second substrate are adjusted to one another and bonded to one another in such a way that when the movable structure deflects, the first contact area may come into contact with the second contact area in order to close an electrical contact.

In one advantageous embodiment of the present invention, at least one first electrical connection is formed between the first and the second substrate.

In one advantageous embodiment of the present invention, the cavity between the two substrates in which the movable structure is situated is completely enclosed and sealed by a bonding frame around the movable structure.

It is also advantageous when at least one second electrical connection between the second contact area and an outer area is established on or in the second substrate. This occurs particularly advantageously by applying a via through the second substrate. It is also advantageous when a wiring layer is applied to the second substrate, with the aid of which the second electrical connection between the second contact area and the outer area is established beneath the bonding frame, on the same side of the second substrate.

In the related art, the distance between the two contacts is created by an etching process with all its limitations. In contrast, in the method according to an example embodiment of the present invention, the distance between the first and the second contact area is created by a wafer bonding process. This allows a freer selection of the contact metals and of the manufacturing method for the movable structure. On the whole, a better and simpler MEMS relay may be achieved. In addition, contact surfaces that are very large and also in parallel are possible, since there are no limitations due to the sacrificial layer etching process.

It is also particularly advantageous that in this arrangement, the electrical contact material that is also largely responsible for the current conduction may be selected separately from the material that is responsible for the mechanics of the movable structure. Thus, in this approach, for example a silicon layer may be utilized that exhibits virtually no fatigue phenomena at typical operating temperatures of a relay. In addition, very large, flat, freestanding surfaces may also be created using silicon layers, so that large electrostatic electrode surfaces are made possible, which due to their low bending may be situated at small distances from the counter electrode in order to be able to generate particularly large electrostatic forces. Silicon functional layers having a thickness of at least 5 μm are particularly advantageous.

Both contact surfaces of the first and second contact areas are freely accessible during the manufacturing process, and may therefore be directionally coated, for example using a vapor deposition process. Furthermore, the contact surfaces may be conditioned with free accessibility, for example using UV light, and cleaned with free accessibility, for example by backsputtering. Lastly, the first contact surface may also be freely structured independently of the second contact surface due to the fact that the first and the second contact surfaces are situated on two different substrates.

It is advantageous to construct the movable MEMS structure in the first substrate from a cavity SOI substrate. In particular, it is thus possible to expose the movable structure only via a trenching process; this allows a very free selection of the contact metal, since a sacrificial layer etching process may thus be avoided. In addition, a monocrystalline silicon layer as a functional layer is particularly advantageous with regard to the mechanical and thermal properties.

Furthermore, it is advantageous to provide a stop 21 between the two substrates in order to limit the collapse or the pressing of the bond connection, and thus to ensure a defined distance between the two substrates and to produce defined mechanical stop conditions for the movable structure.

It is advantageous to also provide the second substrate with an ASIC. In this way, a protective circuit for the relay or a control circuit for the relay may be integrated into the MEMS structure without the need for additional space. In contrast, MEMS relays in the related art, as a module, are very large and costly because an additional ASIC in the module is necessary.

In one particularly advantageous arrangement using vias (TSVs) through the second substrate, and soldering surfaces or solder balls on the rear side of the second substrate, it is even possible to produce a particularly small bare die relay as a chip-level component (cf. FIG. 8).

As a bond connection, an Al layer is advantageously used on the second substrate, and a Ge layer is used on the first substrate. A bond connection that is mechanically very robust with little outgassing in the bonding process may be established in this way. In addition, the connection has good electrical conductivity. This is advantageous in particular when an ASIC is provided in the second substrate, on the side facing the first substrate. Many ASIC processes utilize Al as a strip conductor material, and therefore an Al strip conductor may at the same time also be utilized as a bond layer without the need for additional measures.

In one alternative embodiment of the present invention, a copper-tin-copper bond connection is used. This is advantageous in particular when an ASIC for which the strip conductors are produced from Cu is situated in the second substrate, on the side, the internal side, facing the first substrate.

Moreover, the arrangement may not only be utilized to construct a single relay, but also multiple relays may be integrated on a chip. The wiring on the second substrate may also be advantageously utilized to connect the relays in a variable manner, for example as a matrix.

Furthermore, the metal layers in the second substrate may also be utilized as shielding in order to construct relays that are particularly well shielded or that are designed specifically for high-frequency applications.

Further advantageous embodiments of the present invention are disclosed herein.

### BRIEF DESCRIPTION OF THE DRAWINGS

FIG. 1 schematically shows a capacitively actuatable MEMS switch including an out-of-plane switching element in the related art.

FIG. 2 schematically shows a capacitively actuatable MEMS switch including an in-plane switching element.

FIGS. 3A and 3B schematically show in a first exemplary embodiment a MEMS switch according to the present invention including contacts in the cap in the basic state and in the switched state.

FIG. 4 schematically shows in a second exemplary embodiment a MEMS switch according to the present invention including a metallic additional layer on the functional layer;

FIG. 5 schematically shows in a third exemplary embodiment a MEMS switch according to the present invention including a metallic contact surface that is situated on the functional layer via a second insulating layer.

FIG. 6 schematically shows in a fourth exemplary embodiment a MEMS switch according to the present invention including a wiring layer and bond pads at the internal side of the second substrate.

FIG. 7 schematically shows in a fifth exemplary embodiment a MEMS switch according to the present invention including a stop that determines the distance between the micromechanical functional layer and the second substrate.

FIG. 8 schematically shows in a sixth exemplary embodiment a MEMS switch according to the present invention including an Al—Ge bond connection and a second substrate with an integrated circuit.

FIGS. 9A through 9L show in one exemplary embodiment a method according to the present invention for manufacturing a micromechanical switch at a device, in various stages.

FIG. 10 schematically shows the method according to the present invention for manufacturing a micromechanical switch.

### DETAILED DESCRIPTION OF EXAMPLE EMBODIMENTS

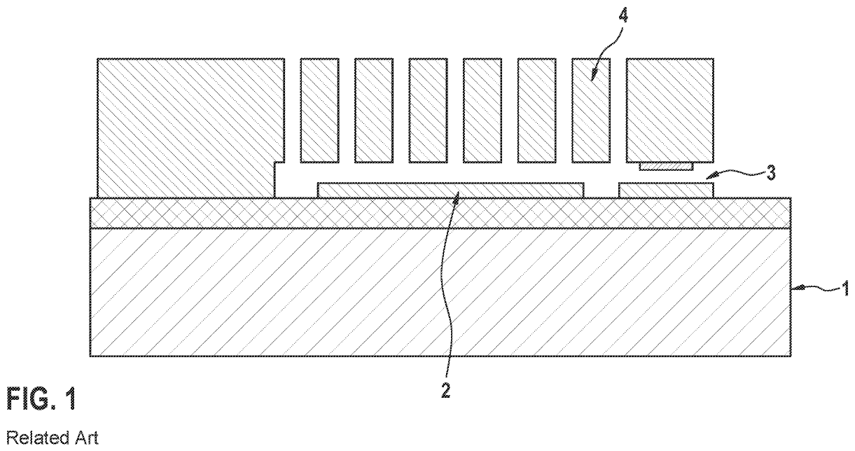

FIG. 1 schematically shows a capacitively actuatable MEMS switch including an out-of-plane switching element in the related art, in a sectional illustration. A first electrode 2 and a first contact surface 3 are provided on a substrate 1. A lever structure 4 is situated above both structures, separated by a distance. If a voltage is applied between the lever and the first electrode, a movement out of the substrate plane (out-of-plane) results. The lever is deflected essentially perpendicularly toward the substrate, and a contact between the lever and the contact surface is established.

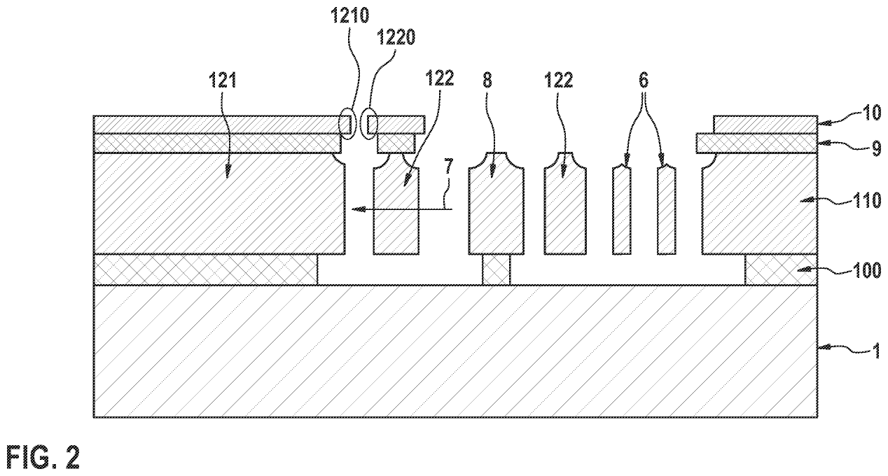

FIG. 2 schematically shows a capacitively actuatable MEMS switch including an in-plane switching element, in a sectional illustration. A first insulating layer 100, a silicon layer 110, a second insulating layer 9, and a metal layer 10 are situated one on top of the other on a substrate 1. The silicon layer, the second insulating layer, and the metal layer together form a micromechanical functional layer in which a fixed portion 121, an electrically actuatable, deflectable switching element 122, and fixed electrodes 8 are formed. The switching element 122 is movably suspended on suspension springs 6. A first contact area 1210 is formed in metal layer 10 of fixed portion 121, and a second contact area 1220 is formed in metal layer 10 of switching element 122. The switching element is deflectable in at least one first direction 7 in parallel to a main plane of extension of the substrate. The first and the second contact area may thus come into mechanical contact with one another and thus close an electrical contact 11. The deflection of switching element 122 is effectuated by applying a voltage to oppositely situated electrode fingers 8 that are anchored to the substrate. First contact area 1210 and second contact area 1220 are each connected to their own strip conductor. An electrical connection between the strip conductors may thus be switched on and off by deflection of switching element 122.

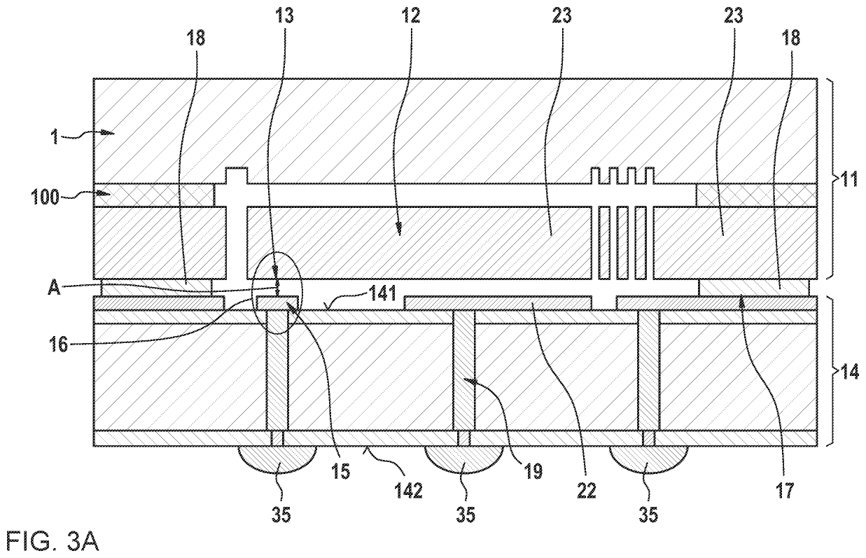

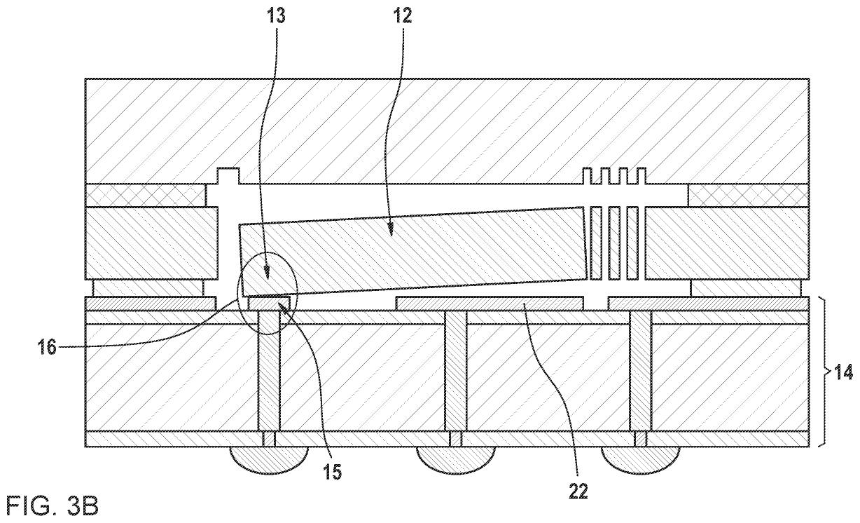

FIGS. 3A and 3B schematically show in a first exemplary embodiment a MEMS switch according to the present invention including contacts in the cap in the basic state and in the switched state.

FIG. 3A schematically shows in a first exemplary embodiment a MEMS switch according to the present invention including contacts in the cap in the basic state. The MEMS switch is made up of a multilayered first substrate 11, which in turn is formed from a silicon substrate 1, a first insulating layer 100, and a micromechanical functional layer 23 that is movable in parts. A deflectable switching element 12 is formed in the micromechanical functional layer. The MEMS switch also includes a second substrate 14 that is connected to the MEMS substrate with the aid of a eutectic bond 18. The second substrate is situated at a distance A above the switching element. The switching element includes an electrically conductive first contact area 13, and is deflectable toward the second substrate (out-of-plane). At an internal side 141 the second substrate includes an electrically conductive second contact area 15 that is situated in such a way that the switching element together with the first contact area may be applied to the second contact area in order to close an electrical contact 16.

Eutectic connection 18 also forms a first electrically conductive connection 17 that is situated between micromechanical functional layer 23 and second substrate 14.

A second electrically conductive connection, namely, a via 19, is situated between second electrical contact area 15 at internal side 141, and an external side 142 of second substrate 14, and is connected to an electrical terminal 35 at the external side, a rear-side contact.

At internal side 141 the second substrate also includes a drive electrode 22 in order to exert a capacitive drive force on switching element 23.

Further vias 19 connect drive electrode 22 and first electrically conductive connection 17 to further electrical terminals 35 at external side 142.

FIG. 3B schematically shows in a first exemplary embodiment a MEMS switch according to the present invention including contacts in the cap in the switched state.

Switching element 12 is deflected toward second substrate 14 via a capacitive action of force of drive electrode 22, so that first contact area 13 rests against second contact area 15, and electrical contact 16 is closed.

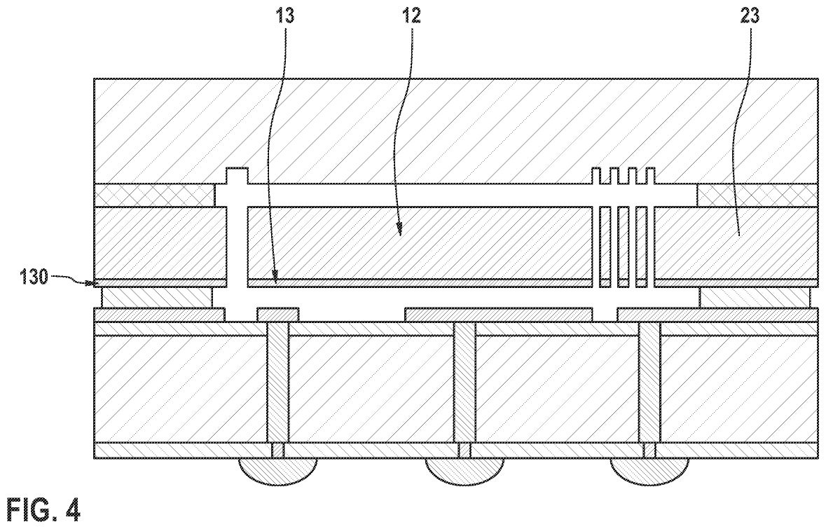

FIG. 4 schematically shows in a second exemplary embodiment a MEMS switch according to the present invention including a metallic additional layer on the functional layer. Metallic additional layer 130 on micromechanical functional layer 23 improves the conductivity of the functional layer, in particular of deflectable switching element 12. A portion of the metallic additional layer also forms first contact area 13.

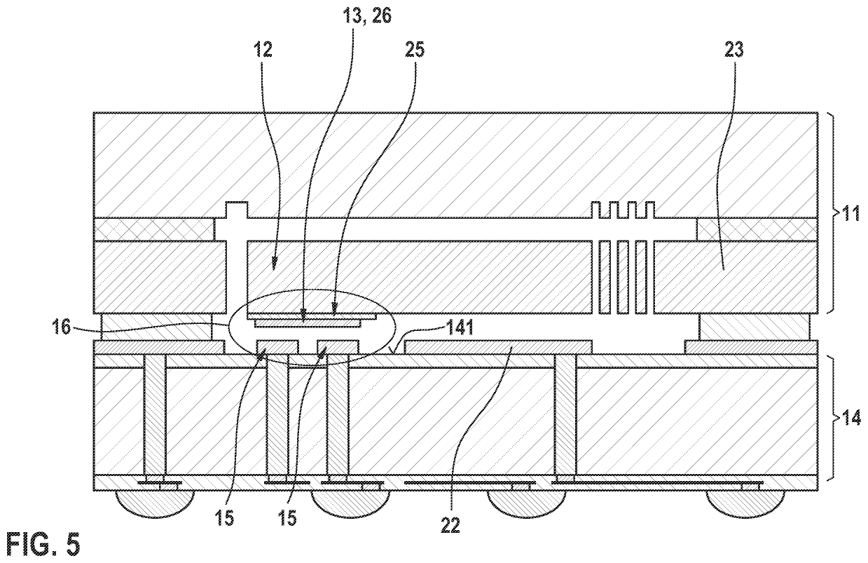

FIG. 5 schematically shows in a third exemplary embodiment a MEMS switch according to the present invention including a metallic contact surface that is situated on the functional layer via a second insulating layer. Metallic contact surface 26 forms first contact area 13, and is electrically insulated from functional layer 23 with the aid of second insulating layer 25.

A relay whose voltage level for activating the relay is galvanically separate from the input and output of the relay may be easily constructed in this way. Second contact areas 15 on internal side 141 of second substrate 14 are situated next to one another primarily for better illustration. In reality, they are preferably situated one behind the other in the plane of the drawing in order to provide a good bridge contact 16.

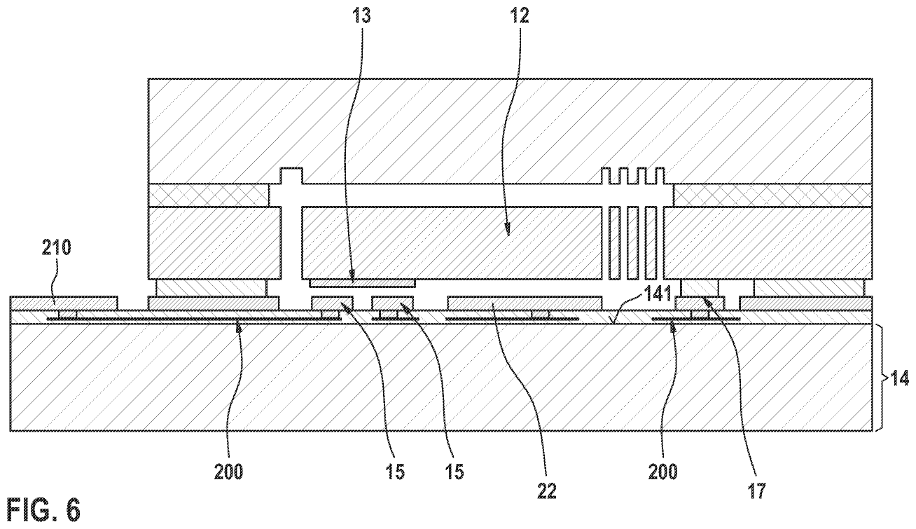

FIG. 6 schematically shows in a fourth exemplary embodiment a MEMS switch according to the present invention including a wiring layer and bond pads at the internal side of the second substrate. A relay is illustrated in which the electrical supply is not led through the substrate as previously, but, rather, is led through outwardly below the bond area on the front side, i.e., the internal side, of the second substrate. For this purpose, a wiring layer 200 is situated at internal side 141 of second substrate 14. The wiring layer is connected to first electrically conductive connection 17, second contacts 15, and drive electrode 22 on the one hand, and to bond pads 210 on the other hand. In addition, FIG. 6 shows an arrangement via which particularly high contact forces may be generated. Electrostatic forces increase as a function of the reciprocal of the squared distance. Therefore, it is important to achieve the smallest possible, well-defined distance between the movable structure and drive electrode 22 in the contact state.

This may be achieved in a particularly advantageous manner using the concept shown here.

For this purpose, on the side of second substrate 14, contact 15 and drive electrode 22 are formed from the same layer, thus making it possible for them to be situated at the same vertical height. To ensure this particularly well, during the manufacturing process either the layer itself or a layer situated beneath this layer may be planarized using a polishing process.

On the opposite side, in first substrate 11 a metallic contact layer 26 for a first contact area 13 may be deposited on switching element 12. No additional material is provided on the switching element in the area of the counter electrode. On the one hand it is advantageous that the distance between the deflectable switching element and drive electrode 22 in the contact state is defined solely by the thickness of metallic contact layer 26, and therefore may be set very precisely. On the other hand, it is advantageous that the surface of the movable structure, due to the use of a cavity SOI substrate, makes it possible to produce very smooth surfaces with little warping as a movable structure above drive electrode 22, which also allows very small distances to be achieved between deflectable switching element 12 and drive electrode 22 in the contact state.

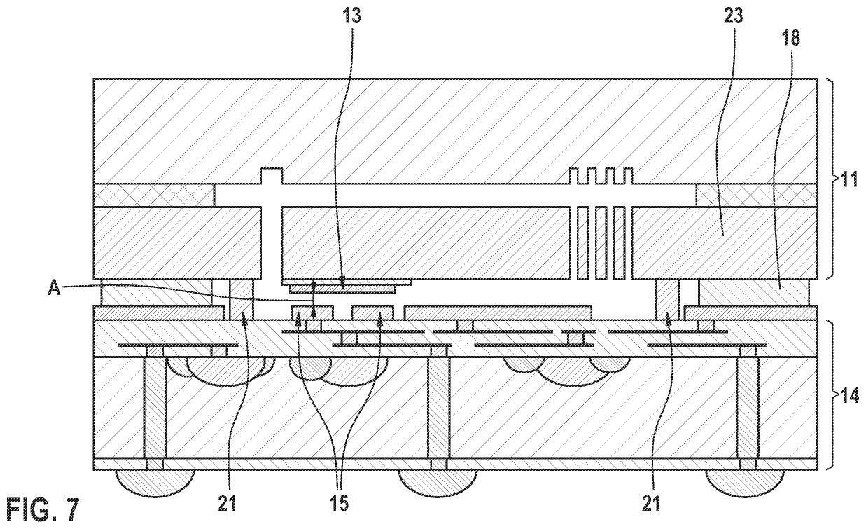

FIG. 7 schematically shows in a fifth exemplary embodiment a MEMS switch according to the present invention including a stop that determines the distance between the micromechanical functional layer and the second substrate. A spacer or stop 21 that determines the ultimate height of bonding frame 18 upon joining of the substrates during manufacture of the device is permanently situated between first substrate 11 and second substrate 14. Thus, these are permanent in situ bond flags. Spacer 21 limits the collapse of the bond connection. As a result, distance A between first contact area 13 and second contact area 15 of the MEMS switch is also precisely set.

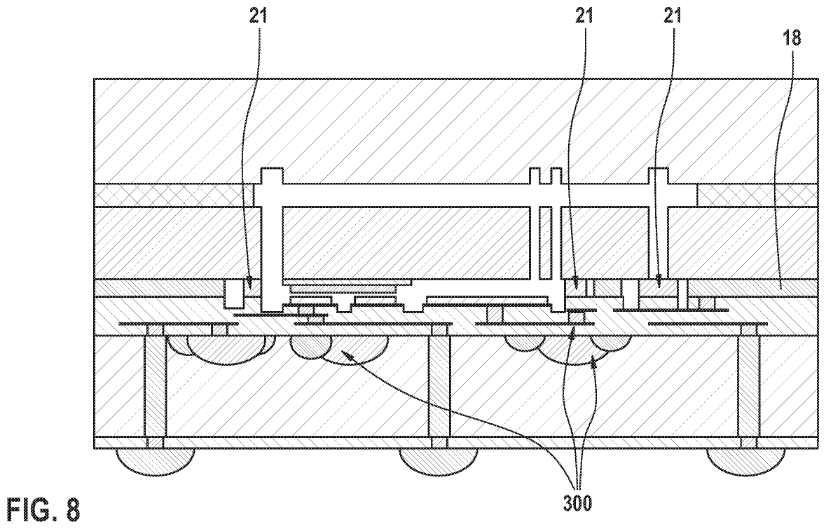

FIG. 8 schematically shows in a sixth exemplary embodiment a MEMS switch according to the present invention including an Al—Ge bond connection and a second substrate with an integrated circuit. IC structures, in the example an ASIC 300, are/is situated at the internal side of second substrate 11. Eutectic bond connection 18 is made up of Al—Ge. Stops 21 determine the height of the bond connection.

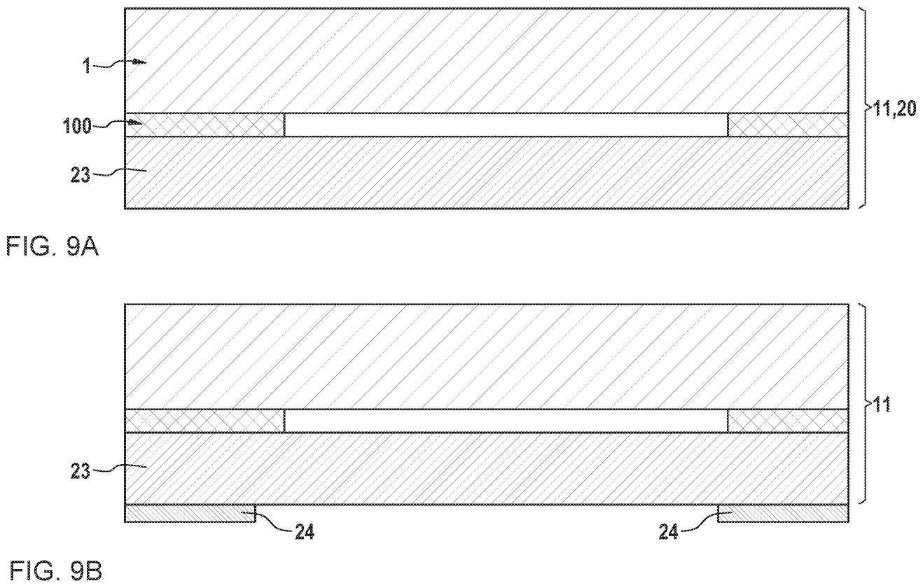

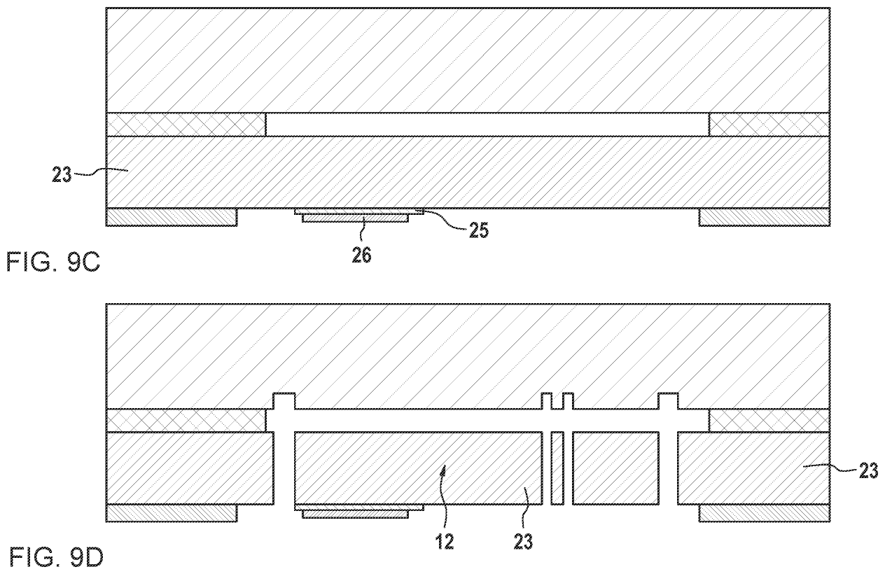

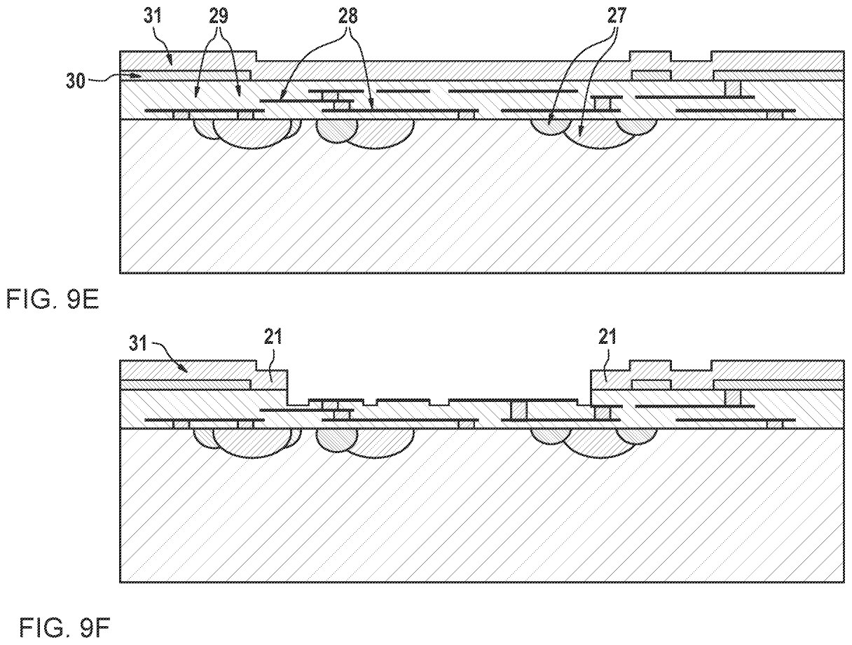

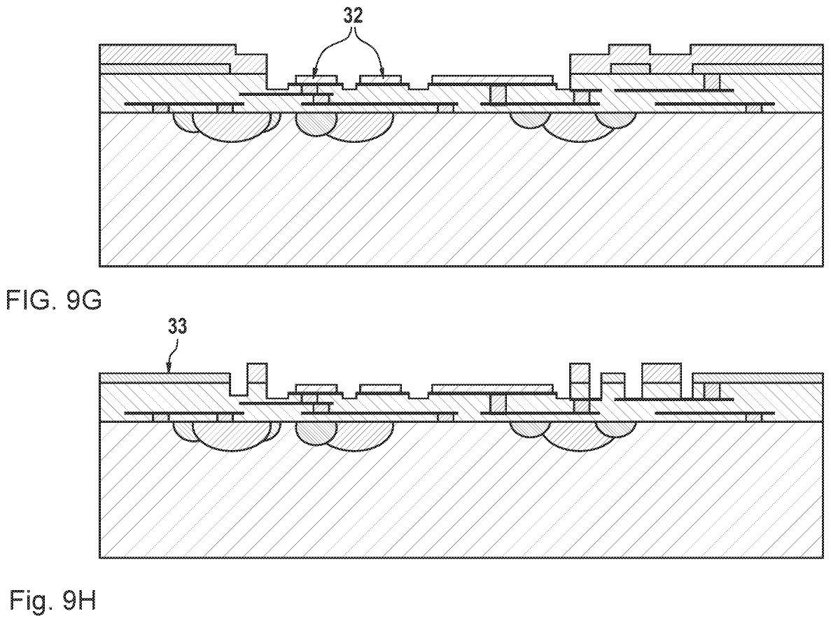

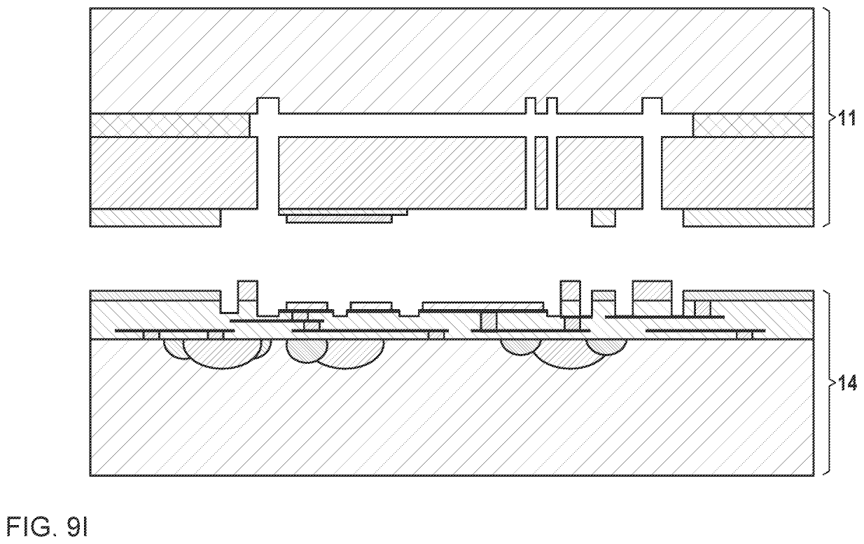

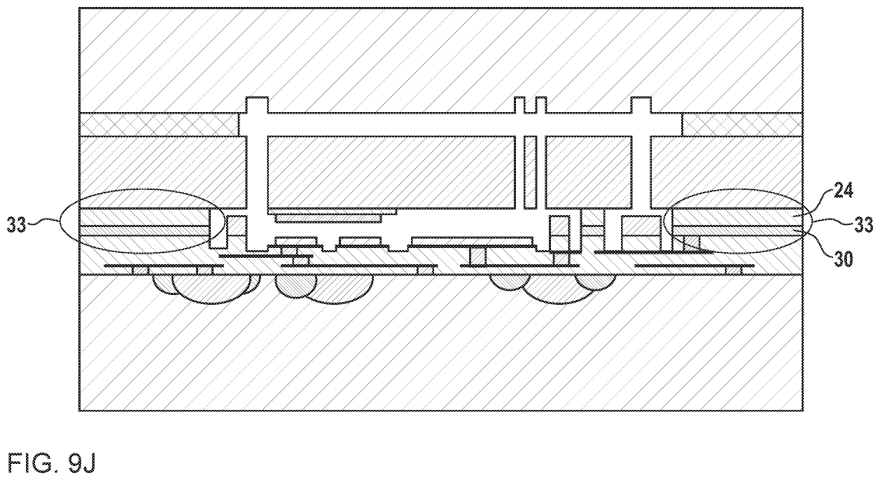

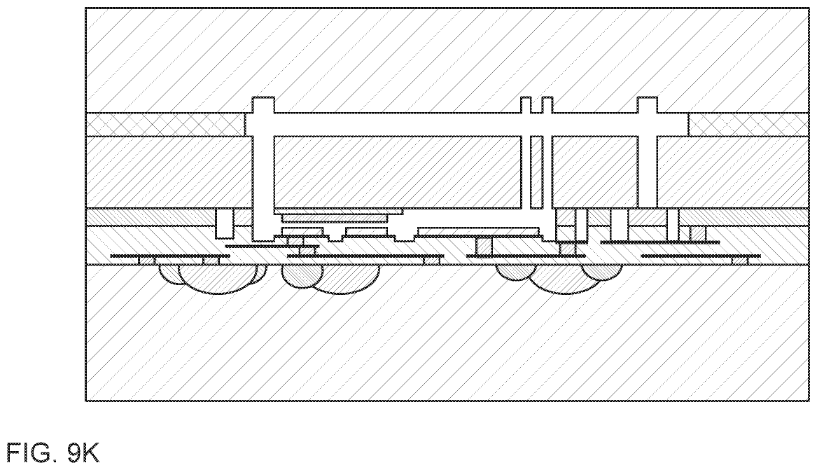

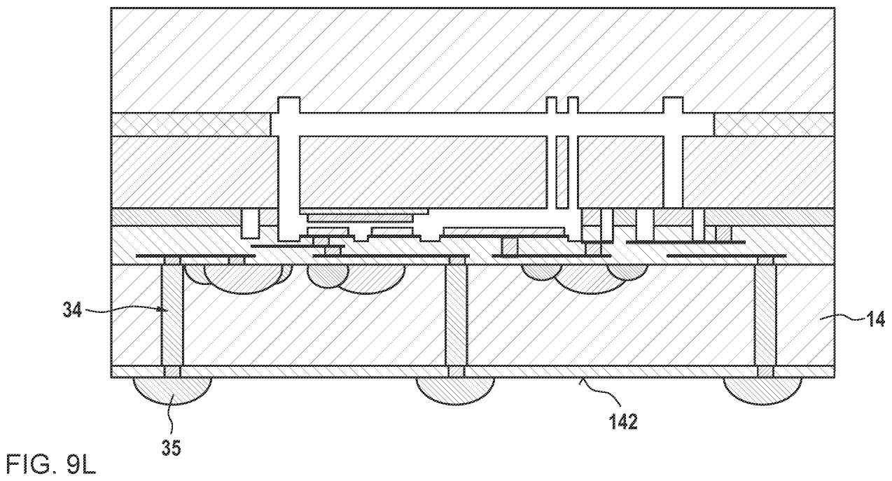

FIGS. 9A through 9L show in one exemplary embodiment a method according to the present invention for manufacturing a micromechanical switch at a device, in various stages.

FIG. 9A shows a first substrate 11. A functional layer 23 is applied to a substrate 1, above a first insulating layer 100. An SOI substrate with a buried cavity, a so-called cavity SOI substrate 20, is preferably utilized.

A germanium layer 24 is deposited and structured on micromechanical functional layer 23 of first substrate 11 (FIG. 9B).

A dielectric layer 25, preferably a PECVD oxide layer or PECVD nitride layer, is also deposited on micromechanical functional layer 23. A metallic contact layer 26 is deposited thereon and structured. A noble metal layer, a tungsten layer, a ruthenium layer, or an iridium layer is preferably deposited here. The dielectric layer is structured (FIG. 9C).

Functional layer 23 is structured and exposed. In particular, a switching element 12 is created that is deflectable in a direction perpendicular to a main plane of the substrate (out-of-plane). A trenching process is preferably used (FIG. 9D).

FIG. 9E shows a second substrate 14. A first strip conductor layer 28 is deposited on the second substrate, above a dielectric layer, and structured. In particular, an ASIC wafer with an integrated circuit 27 may be used in the second substrate. In addition, the circuit may advantageously be utilized as a functional element or as a protective element for the MEMS relay. A further dielectric layer 29 is deposited and structured. An aluminum layer 30 is deposited and structured.

A further dielectric layer 31 is optionally deposited and structured (FIG. 9F). By use of this layer, a stop structure 21 is created in partial areas. The layer thickness is selected in such a way that during the bonding process the Al layer and the Ge layer may make contact, but at the same time the distortion of the two layers during the bonding process is limited. Via the structuring, the first strip conductor layer may also be exposed and utilized as a second contact surface.

A second contact surface 32 may now optionally be deposited and structured (FIG. 9G). A noble metal layer, a tungsten layer, a ruthenium layer, or an iridium layer is preferably used.

The further dielectric layer in bond areas 33 is now optionally removed in a further structuring step (FIG. 9H). Stops 21 are exposed.

First substrate 11 is situated above second substrate 14, with its front side facing the second substrate (FIG. 9I).

The two substrates are adjusted to one another (FIG. 9J), germanium layer 24 and aluminum layer 30 in bond areas 33 being brought into contact with one another. The two substrates are bonded (FIG. 9K).

A bonding process at a temperature between 400° C. and 480° C. is preferably used.

In the second substrate, at least one electrical connection is established between the area enclosed by the bond connection and an outer area.

Second substrate 14 is preferably thinned from the rear side.

An electrical connection 34, a via (TSV), is established through the second substrate.

A wiring layer is optionally applied to the rear side of the second substrate.

Contact surfaces 35, in particular solderable surfaces or solder balls, are applied to rear side 142 of second substrate 14 (FIG. 9L).

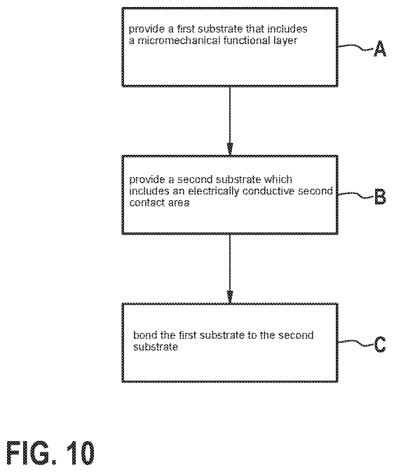

FIG. 10 schematically shows the method according to the present invention for manufacturing a micromechanical switch, including the essential steps:

A—providing a first substrate that includes a micromechanical functional layer in which a deflectable switching element that includes an electrically conductive first contact area is formed;
B—providing a second substrate which at an internal side includes an electrically conductive second contact area;
C—bonding the first substrate to the second substrate, whose internal side faces the first substrate, and the first contact area and the second contact area being situated at a distance from one another in such a way that the deflectable switching element together with the first contact area may be applied to the second contact area in order to close an electrical contact.

### LIST OF REFERENCE NUMERALS

1 substrate
2 first electrode
3 first contact surface
4 lever structure
5 (removed) sacrificial layer
6 suspension springs
7 first direction
8 fixed electrode
9 second insulating layer
10 metal layer
11 first substrate, MEMS substrate
12 deflectable switching element
13 first contact area
14 second substrate, cap substrate
15 second contact area
16 contact
17 first electrical connection
18 bonding frame
19 second electrical connection
21 stop
22 drive electrode
23 functional layer that is movable in parts
24 Ge layer
25 second insulating layer, dielectric layer
26 metallic contact layer
27 ASIC
28 first strip conductor
29 further dielectric layer
30 aluminum layer
31 dielectric layer
32 second contact surface
33 bond area
34 via (through-silicon via (TSV))
35 rear-side contact surface
130 metallic additional layer
141 internal side of the second substrate
142 external side of the second substrate
100 first insulating layer
110 silicon layer
120 micromechanical functional layer
121 fixed portion
122 deflectable switching element
1210 first contact area
1220 second contact area
A distance
200 wiring layer
210 bond pad
300 integrated circuit (ASIC)

1-15. (canceled)

16. A micromechanical switch, comprising:
a first substrate with a micromechanical functional layer in which a deflectable switching element is formed;
a second substrate that is connected to the first substrate, the second substrate being situated at a distance above the switching element, the switching element including an electrically conductive first contact area and being deflectable toward the second substrate, wherein the second substrate at an internal side facing the first substrate includes an electrically conductive second contact area that is situated in such a way that the switching element together with the first contact area may be applied to the second contact area in order to close an electrical contact.

17. The micromechanical switch as recited in claim 16, wherein a first electrically conductive connection is situated between the micromechanical functional layer and the second substrate, the first electrically conductive connection being a eutectic bond.

18. The micromechanical switch as recited in claim 16, wherein a second electrically conductive connection is situated between the second electrical contact area at the internal side and an external side of the second substrate, wherein the second electrically conductive connection is a via.

19. The micromechanical switch as recited in claim 16, wherein the first substrate and the second substrate are connected to one another using a bonding frame, and a third electrical connection in a wiring layer is situated between the second electrical contact area at the internal side and a bond pad at the internal side, the third electrical connection passing beneath the bonding frame.

20. The micromechanical switch as recited in claim 16, wherein an electrically activatable electrode surface is situated on the second substrate in partial areas beneath the micromechanical functional layer.

21. The micromechanical switch as recited in claim 16, wherein a first electrical contact is completely enclosed by a bonding frame.

22. The micromechanical switch as recited in claim 16, wherein the first contact area is applied to the deflectable switching element entirely via an electrically insulating second insulating layer.

23. The micromechanical switch as recited in claim 16, wherein the first electrical contact protrudes in a vertical direction less than 25% beyond the micromechanical functional layer relative to a vertical distance of the first contact area from the second contact area in an undeflected state of the switching element.

24. The micromechanical switch as recited in claim 16, wherein the second electrical contact area in a vertical direction is situated at the same height as a drive electrode, or at least does not differ by more than 10% in height relative to a vertical distance of the first contact area from the second contact area, in an undeflected state of the switching element.

25. The micromechanical switch as recited in claim 16, wherein the micromechanical functional layer is completely or partially made of silicon.

26. The micromechanical switch as recited in claim 25, wherein the micromechanical functional layer in a vertical direction has at least a height of 5 μm.

27. The micromechanical switch as recited in claim 16, wherein the first contact area and/or the second contact area is made of a metallic material.

28. A method for manufacturing a micromechanical switch, comprising the following steps:
A) providing a first substrate that includes a micromechanical functional layer in which a deflectable switching element that includes an electrically conductive first contact area is formed;
B) providing a second substrate which at an internal side includes an electrically conductive second contact area;
C) bonding the first substrate to the second substrate, whose internal side faces the first substrate, and the first contact area and the second contact area being situated at a distance from one another in such a way that the deflectable switching element together with the first contact area may be applied to the second contact area in order to close an electrical contact.

29. The method for manufacturing a micromechanical switch as recited in claim 28, wherein a cavity SOI substrate is provided as the first substrate in step A.

30. The method for manufacturing a micromechanical switch as recited in claim 28, wherein at least one layer at the internal side of the second substrate and/or at an opposite side of the first substrate that is oriented toward the internal side, is planarized.
